(19) United States
(12) Patent Application Publication
(10) Pub. No.: US 2026/0305452 A1
(43) Pub. Date: Oct. 1, 2026

(54) BONDED SEMICONDUCTOR STRUCTURES

(71) Applicant: GlobalFoundries Singapore Pte. Ltd., Singapore (SG)

(72) Inventors: Ranjan Rajoo, Singapore (SG); Chia Yee Chong, Singapore (SG); Hong Ting Toh, Singapore (SG)

(21) Appl. No.: 19/091,050

(22) Filed: Mar. 26, 2025

(51) Int. Cl. H01L 23/31; H01L 21/56; H01L 23/29; H01L 25/07

(52) U.S. Cl. CPC H10W 74/121; H10W 74/014; H10W 74/134; H10W 74/43; H10W 74/47; H10W 90/00

(57) ABSTRACT

The present disclosure relates to semiconductor structures and, more particularly, to a chip bonded to a wafer and methods of manufacture. The structure includes: a wafer; a chip bonded to the wafer; and a continuous liner on an upper surface of the chip and extending on all sidewalls of the chip.

### BACKGROUND

The present disclosure relates to semiconductor structures and, more particularly, to a chip bonded to a wafer and methods of manufacture.

Chip to wafer hybrid bonding is a packaging technique that joins chips or wafers together directly. Typically, the chip to wafer hybrid bonding is used to create 3D stacks of chips, which can improve performance and reduce power consumption. The chip to wafer hybrid bonding is a bumpless processes which avoids the problems associated with solder-based bump technologies. For example, the chip to wafer hybrid bonding can achieve ultra-fine pitch interconnects. The chip to wafer hybrid bonding can be used to create 3D stacked memory, CPU, GPU, FPGA, or SoC technologies.

### SUMMARY

In an aspect of the disclosure, a structure comprises: a substrate; a chip mounted to the substrate; and a continuous liner on an upper surface of the chip and extending on all sidewalls of the chip.

In an aspect of the disclosure, a structure comprises: a substrate; and a chip comprising a continuous liner on a backside of the chip and partially on all sidewalls of the chip, the chip further comprising a mounting surface that is devoid of the continuous liner and which is mounted to the substrate.

In an aspect of the disclosure, a method comprises: partially dicing a device substrate from a first side of the device substrate; lining the first side of the device substrate with a continuous liner material on all of the sidewalls which are formed at a region of the partially dicing; completing the dicing of the device substrate from a second side of the device substrate to form a plurality of chips; and mounting the second side of each of the plurality of chips to a substrate with the continuous liner now being on an upper surface and all of the sidewalls of the chip, the upper surface being opposite to a mounting surface of the chip to the substrate.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows another structure and respective fabrication processes in accordance with aspects of the present disclosure.

FIGS. 3A-3C show top views of different patterned features on top surface of the chip shown in FIG. 2 in accordance with aspects of the present disclosure

FIGS. 4 and 5 show different structures and respective fabrication processes in accordance with aspects of the present disclosure.

FIG. 6 shows top view of the structure of FIG. 4 in accordance with aspects of the present disclosure.

FIGS. 7A-7F show fabrication processes to manufacture the structures shown in FIGS. 1 and 2 in accordance with aspects of the present disclosure.

FIGS. 8A-8F show different fabrication processes to manufacture the structures shown in FIGS. 1 and 2 in accordance with aspects of the present disclosure.

FIGS. 9A-9F show fabrication processes to manufacture the structures shown in FIGS. 3 and 4 in accordance with aspects of the present disclosure.

### DETAILED DESCRIPTION

The present disclosure relates to semiconductor structures and, more particularly, to a chip bonded to a wafer and methods of manufacture. More specifically, in embodiments, the chip includes a liner on its sides and upper surface (relative to the mounting surface of the chip to a wafer). The liner will prevent warpage and breakage of the chip during pick and place processes, e.g., during lifting operations to place the chip onto the wafer. Advantageously, the liner will strengthen the chip, e.g., chip corners, which will prevent cracking or chipping of the chip, in addition to preventing warpage of the chip. The liner also acts an as adhesion layer for gap fill material. The use of the liner also eliminates a two (2) step grinding process otherwise needed during chip to wafer interconnection.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes. In particular, the fabrication of the structures uses three basic building blocks: (i) deposition of thin films of material on a chip (die), (ii) applying a patterned mask on top of the films by photolithographic imaging, and (iii) etching the films selectively to the mask.

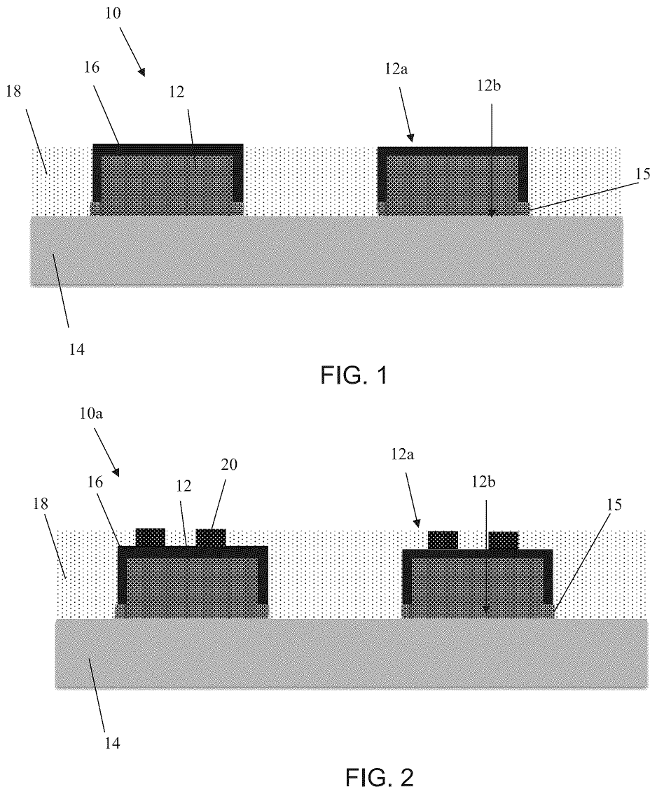

FIG. 1 shows a structure and respective fabrication processes in accordance with aspects of the present disclosure. The structure 10 includes a chip 12 mounted (e.g., bonded) to a substrate 14 (hereinafter referred to as a wafer 14) as is understood by a skilled person in the art such that no further explanation is required for a complete understanding of the disclosure. It should be understood by those of ordinary skill in the art that the chip 12 includes circuitry comprising active and/or passive devices formed on a semiconductor substrate, in addition to back-end-of-line (BEOL) structures such as wiring layers and via interconnect structures. It should also be understood that the surface 12a is a backside of the chip 12. The backside of the chip 12 is an upper or exposed surface 12a with respect to the opposing surface 12b which is mounted (e.g., bonded) to the wafer and which is devoid of any liner 16. This is due to the fact that the chip 12 needs to be flipped over (turned upside down) to mount the chip 12 to the wafer 14.

FIG. 1 further shows a liner 16 on surfaces of the chip 12. For example, in embodiments, the liner 16 may be provided on all of the sidewalls and the exposed (e.g., upper surface) 12a of the chip 12 (e.g., referred to as an upper surface when mounted to the wafer 14). Illustratively, in one embodiment, the liner 16 may be provided on five sides of the chip 12, e.g., four sidewalls and the upper surface 12a. The liner 16 may also be continuous on the upper surface 12a and the sidewalls of the chip 12. In further embodiments, the liner 16 partially extends onto the sidewalls of the chip 12. For example, the liner 16 extends on and from the upper surface 12a of the chip 12, and partially downward on the sidewalls of the chip 12. Accordingly, in this and other embodiments, the liner 16 does not extend to the wafer 12 or completely on sidewalls of the chips 12 due to the fabrication processes described herein. In this way, the sidewalls at the bottom portion 15 of the chip 12 may be flush or planar with the liner 16, as this portion 15 is devoid of the liner 16 (e.g., exposed) and separates the liner 16 from the wafer 14.

The liner 16 may be, for example, silicon nitride, titanium nitride, titanium tungsten, tantalum nitride, nickel or copper, amongst other materials that may adhere to a gap fill material 18. The liner 16 may be deposited on the sidewalls and surface 12a of the chip 12 by conventional deposition methods, e.g., chemical vapor deposition (CVD) process. The liner 16 may be a single film or multiple films, with a thickness that prevents warpage of the chip 12 during a pick and place process. Further, the liner 16 can have different thicknesses depending on the dimensions of the chip 12, thereby preventing chip warpage. For example, the thickness of the liner 16 and the thickness of the chip 12 may have an inverse relationship, e.g., a thinner chip may warrant a thicker liner and vice versa.

The gap fill material 18 may be an oxide material deposited by a conventional CVD process on the wafer 14 and the chip 12. The gap fill material 18 may be subjected to a chemical mechanical polishing (CMP). In this way, the gap fill material 18 may be planar with the upper surface 12a of the chip 12 and, more specifically, planar with the liner 16 on the upper surface 12a of the chip 12. The gap material 18 may also contact the exposed bottom portion 15 of the chip 12, itself.

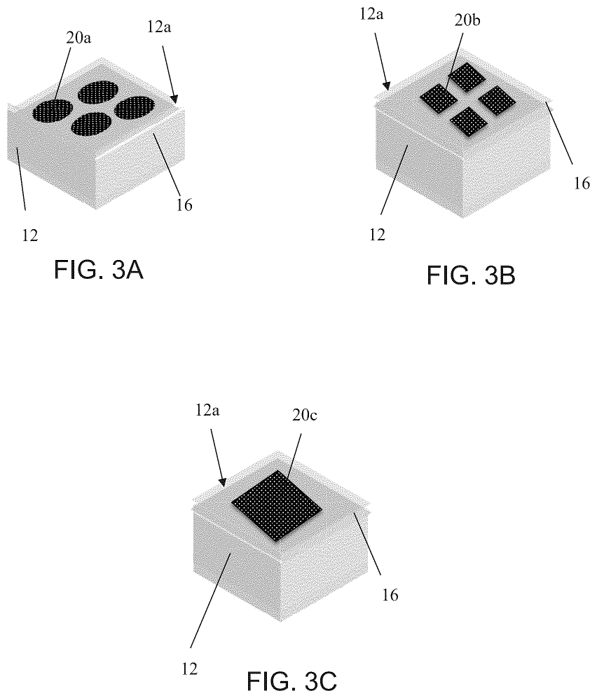

FIG. 2 shows another structure and respective fabrication processes in accordance with aspects of the present disclosure. The structure 10a includes the chip 12 bonded to the wafer 14 at surface 12b as already described herein. The chip 12 also includes the liner 16 as described with respect to FIG. 1. In addition, the chip 12 includes patterned features 20 on the upper surface 12a of the chip 12 and, more specifically, on the liner 16 formed on the upper surface 12a. The patterned features 20 may be, for example, polymer material patterned in one of many different patterns as shown in FIGS. 3A-3C. The polymer material may be, for example, low temperature cure polymer, a benzocyclobutene (BCB) polymer, or a polyimide (PI) polymer, which may contain imide groups belonging to the class of high-performance plastics. The remaining features of the structure 10a of FIG. 2 are similar to the structure 10 of FIG. 1 such that no further explanation is required for a complete understanding of the present disclosure.

FIGS. 3A-3C show top views of different patterned features on the upper surface 12a of the chip 12. For example, in FIG. 3A, a plurality of patterned cylindrical features 20a may be provided on the upper surface 12a of the chip 12. In FIG. 3B, a plurality of the patterned polygon features 20b may be provided on the upper surface 12a of the chip 12. Although the patterned polygon features 20b are represented as squares, it should be understood by those of skill in the art that patterned polygon features 20b may be different polygon shapes such as triangles, rectangles, pentagons, hexagons, octagons, etc. In FIG. 3C, there is a single patterned feature 20c. This single patterned feature 20c may be cylindrical; although other shapes as already described herein are contemplated to prevent cracking and warpage of the chip 12.

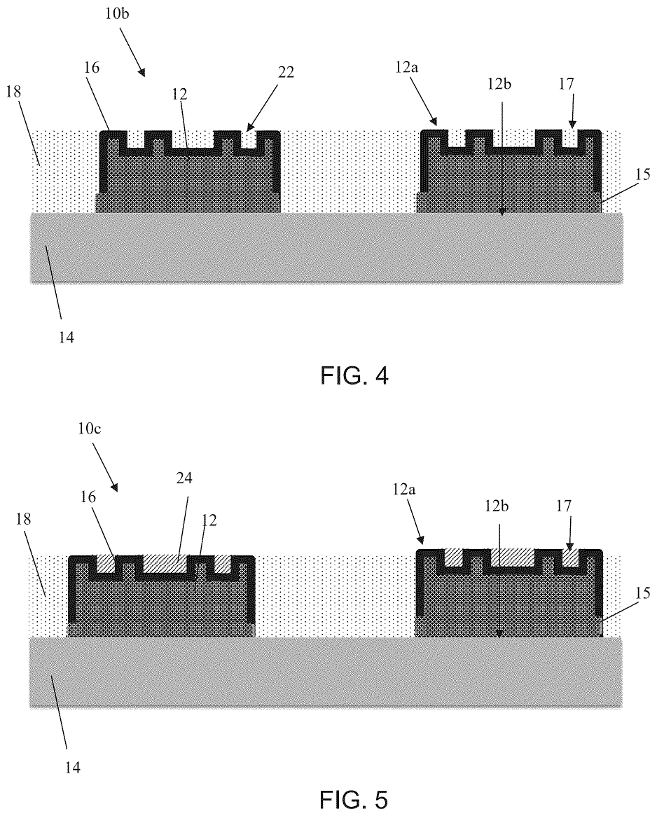

FIGS. 4 and 5 show different structures and respective fabrication processes in accordance with aspects of the present disclosure. In FIG. 4, the structure 10b includes a pattern (e.g., trenches) 17 on the upper surface 12a of the chip 12. The pattern 17 may be formed by a conventional lithography and etching processes on the upper surface 12a of the chip, prior to the formation of the liner 16. The pattern 17 may include one or more trenches or recesses in the upper surface 12a of the chip 12. The pattern 17 may also be lined with the liner 16. The pattern 17, e.g., recesses or trenches, may be filled with insulator material 22, e.g., oxide or nitride or combinations thereof, over the liner 16. The insulator material 22 may be the same material as the gap fill material 18. Also, the insulator material 22 may be subjected to a CMP process such that the upper surface of the liner 16 is planar and an upper surface of the insulator material 22. The remaining features of FIG. 4 are similar to the structure 10a of FIG. 3 such that no further explanation is required for a complete understanding of the present disclosure.

In FIG. 5, the structure 10c includes the pattern 17 on the upper surface 12a of the chip 12 as described with respect to FIG. 4. The pattern 17, e.g., recesses or trenches, may also be filled with polymer material 24. The polymer material 24 may be, for example, low temperature cure polymer, a benzocyclobutene (BCB) polymer, polyimide (PI) polymer, which may contain imide groups belonging to the class of high-performance plastics. Also, the polymer material 24 may be subjected to a CMP process such that upper surface of the liner 16 is planar and an upper surface of polymer material 24. The remaining features of the structure 10c of FIG. 5 are similar to the structure 10b of FIG. 4 such that no further explanation is required for a complete understanding of the present disclosure.

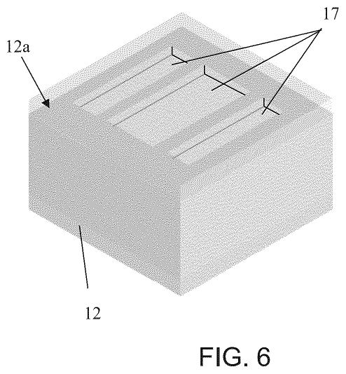

FIG. 6 shows a top view of the patterned feature 17 on the upper surface 12a of the chip 12. For example, the patterned feature 17 may be multiple trenches comprising a polygon shape. It should be recognized by one of skill in the art that although the patterned features 17 are represented as rectangles, they may be different polygons such as triangles, squares, pentagons, hexagons, octagons, etc. In addition, the patterned feature 17 may be circular, oval etc., and may be a single or multiple shapes.

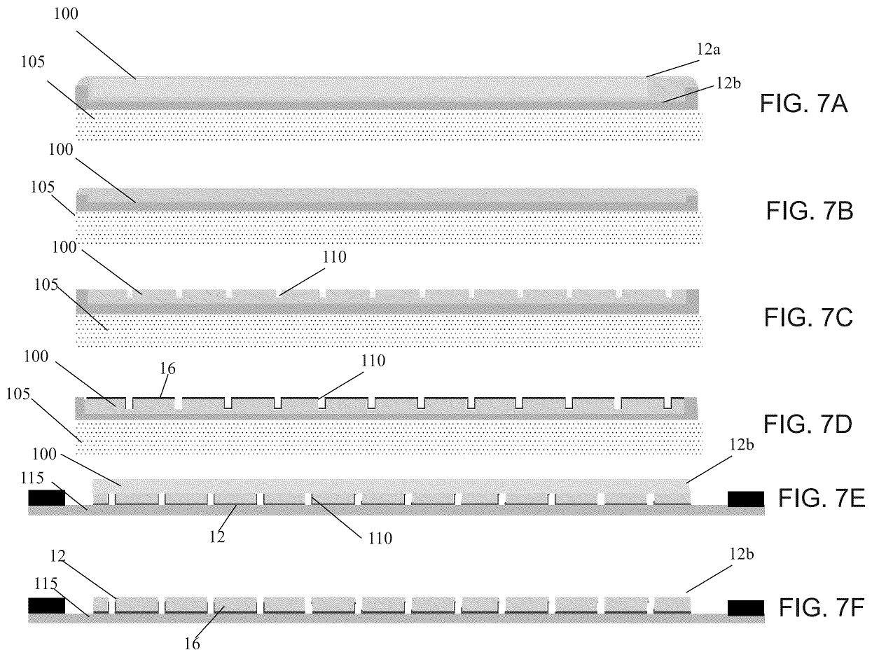

FIGS. 7A-7F show fabrication processes to manufacture the structures shown in FIGS. 1 and 2 in accordance with aspects of the present disclosure. In FIG. 7A, a device wafer 100 may be provided on a carrier 105 with the surface 12a facing upwards and the surface 12b facing downwards. In embodiments, the carrier 105 may be Si or a glass wafer, as illustrative non-limiting examples. In the example of FIG. 7A, the device wafer 100 may be diced to form the chips.

In FIG. 7B, the device wafer 100 may be thinned using, for example, conventional CMP processes. In FIG. 7C, the device wafer 100 may undergo a partial plasma dicing (e.g., etching) process to form trenches 110 partially within the device wafer 100. For example, a resist formed over the device wafer 100 is exposed to energy (light) and developed utilizing a conventional resist developer to form a pattern (opening). An etching process with a selective chemistry, e.g., reactive ion etching (RIE), will be used to transfer the pattern to the device wafer 100 to form the trenches 110. The resist may be removed by a conventional oxygen ashing process or other known stripants.

In FIG. 7D, the liner 16 may be formed on the surface 12a and within the trenches 110. The liner 16 may be formed by conventional deposition methods, e.g., CVD process. The liner 16 may be one or more films as already described herein.

In FIG. 7E, the partially diced device wafer 100 may be removed (separated) from the carrier, flipped over and placed onto a tape frame 115, with the surface 12b (now facing upwards). In FIG. 7F, the partially diced device wafer may be further etched (e.g., diced) starting from the surface 12b to form a plurality of diced chips 12. As in each of the embodiments, the etching process will align with the trenches 110. The diced chips 12 can now be removed from the tape frame 115 and individually mounted onto the wafer 14 with the surface 12b being the mounting surface.

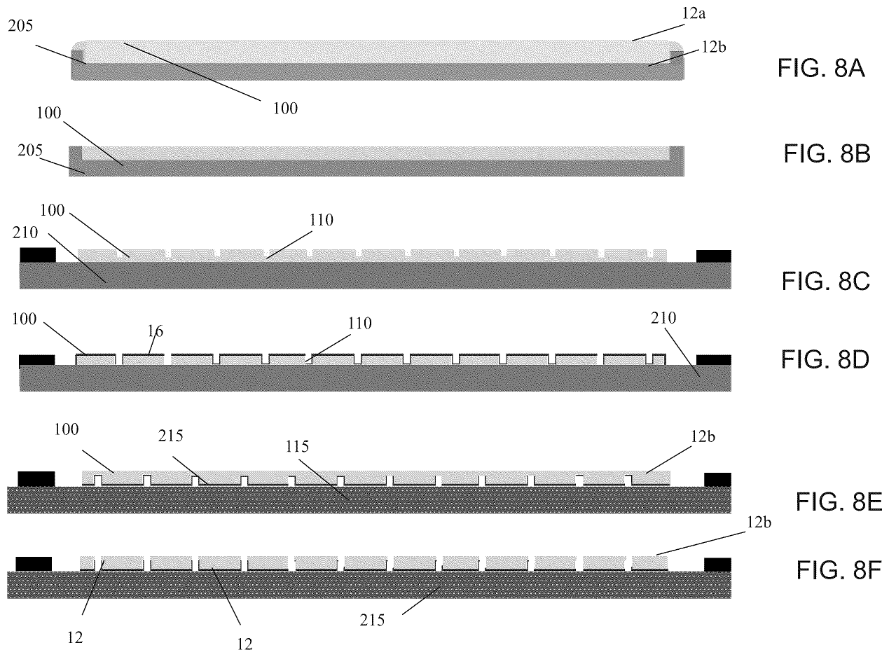

FIGS. 8A-8F show alternative fabrication processes to manufacture the structures shown in FIGS. 1 and 2 in accordance with aspects of the present disclosure. In FIG. 8A, the device wafer 100 may be provided on back grinding tape 205 with the surface 12a facing upwards and the surface 12b facing downwards.

In FIG. 8B, the device wafer 100 may be thinned using, for example, conventional CMP processes. In FIG. 8C, the device wafer 100 may be separated from the back grinding tape and mounted onto a high temperature tape 210 as is known in the art. In this stage of processing, the device wafer 100 may undergo a partial plasma dicing (e.g., etching) process to form the trenches 110 partially extending into the device wafer 100 as already described herein.

In FIG. 8D, the liner 16 may be formed on the surface 12a and within the trenches 110. The liner 16 may be formed by conventional deposition methods, e.g., CVD process. The liner 16 may be one or more films as already described herein.

In FIG. 8E, the partially diced device wafer 100 may be removed (separated) from high temperature tape 210, flipped over and placed onto a dicing tape 215, with the surface 12b (top surface of the chip) facing upwards. In FIG. 8F, the partially diced device wafer may be further etched (e.g., diced) starting from the surface 12b to form a plurality of diced chips 12. As in each of the embodiments, the etching process will align with the trenches 110. The diced chips 12 can now be removed from the dicing tape 215 and individually mounted onto the wafer 14 with the surface 12b being the mounting surface.

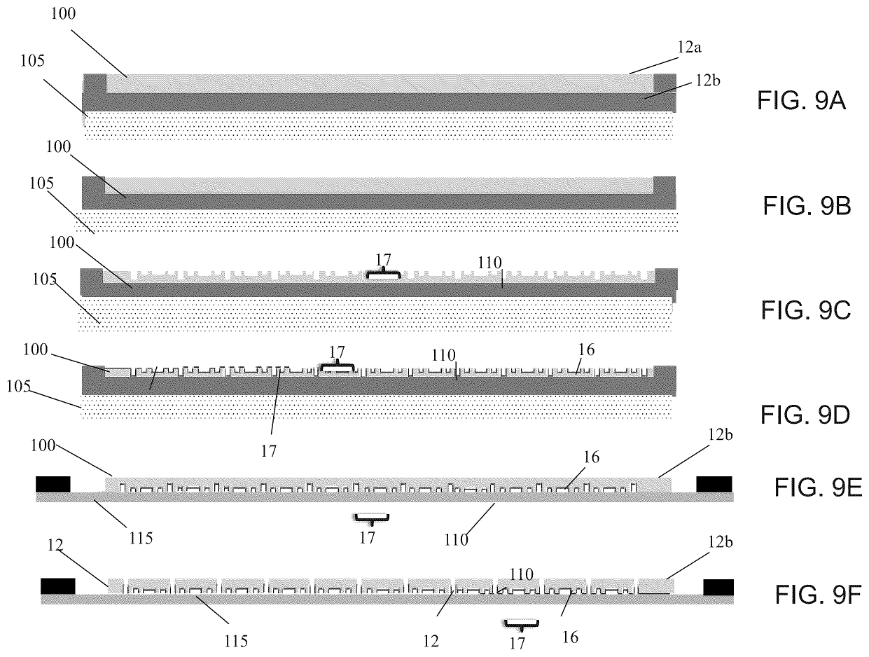

FIGS. 9A-9F show fabrication processes to manufacture the structures shown in FIGS. 3 and 4 in accordance with aspects of the present disclosure. The processes shown in FIGS. 9A-9F are similar to the processes shown with respect to FIGS. 7A-7F, with the exception of the patterning of pattern (e.g., trenches) 17.

In FIG. 9A, a device wafer 100 may be provided on a carrier 105 with the surface 12a facing upwards and the surface 12b facing downwards. In embodiments, the carrier 105 may be Si or a glass wafer, as illustrative non-limiting examples. In the example of FIG. 9A, the device wafer 100 may be diced to form the chips.

In FIG. 9B, the device wafer 100 may be thinned using, for example, conventional CMP processes. In FIG. 9C, the device wafer 100 may undergo a partial plasma dicing (e.g., etching) process to form trenches 110 partially within the device wafer 100. In addition, the device wafer 100 may undergo patterning to form the pattern 17. It should be understood that the trenches 110 and the pattern 17 may be formed in the same processing steps using the processes as already described herein.

In FIG. 9D, the liner 16 may be formed on the surface 12a and within the trenches 110 and the pattern 17. The liner 16 may be formed by conventional deposition methods, e.g., CVD process. The liner 16 may be one or more films as already described herein.

In FIG. 9E, the partially diced device wafer 100 may be removed (separated) from the carrier, flipped over and placed onto a tape frame 115, with the surface 12b (now facing upwards). In FIG. 9F, the partially diced device wafer may be further etched (e.g., diced) starting from the surface 12b to form a plurality of diced chips 12. As in each of the embodiments, the etching process will align with the trenches 110. The diced chips 12 can now be removed from the tape frame 115 and individually mounted onto the wafer 14 with the surface 12b being the mounting surface.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a substrate;
a chip mounted to the substrate; and
a continuous liner on an upper surface of the chip and extending on all sidewalls of the chip.

2. The structure of claim 1, wherein the continuous liner extends partially on the sidewalls of the chip.

3. The structure of claim 2, wherein the sidewalls of the chip are exposed below the continuous liner.

4. The structure of claim 2, wherein a bottom portion of the sidewalls adjacent to the substrate are flush with the continuous liner.

5. The structure of claim 1, further comprising a gap fill material on the substrate and adjacent to the chip, the gap fill material being planar with the continuous liner on the upper surface of the chip.

6. The structure of claim 1, further comprising a patterned feature comprising polymer material on the continuous liner over the upper surface of the chip.

7. The structure of claim 6, wherein the polymer material comprises one of low temperature cure polymer, a benzocyclobutene (BCB) polymer and a polyimide (PI) polymer.

8. The structure of claim 1, wherein the continuous liner comprises one of silicon nitride, titanium nitride, titanium tungsten, tantalum nitride, nickel and copper.

9. The structure of claim 1, wherein the chip comprises at least one trench on the upper surface of the chip, the at least one trench is lined with the continuous liner.

10. The structure of claim 9, wherein the at least one trench is filled with polymer material over the continuous liner.

11. A structure comprising:
a substrate; and
a chip comprising a continuous liner on a backside of the chip and partially on all sidewalls of the chip, the chip further comprising a mounting surface that is devoid of the continuous liner and which is mounted to the substrate.

12. The structure of claim 11, wherein the continuous liner extends partially on the sidewalls of the chip such that the sidewalls of the chip are exposed below the continuous liner.

13. The structure of claim 12, wherein a bottom portion of the sidewalls adjacent to the substrate are flush with the continuous liner.

14. The structure of claim 11, further comprising patterned polymer material on the continuous liner.

15. The structure of claim 14, wherein the polymer material comprises one of low temperature cure polymer, a benzocyclobutene (BCB) polymer and a polyimide (PI) polymer.

16. The structure of claim 11, wherein the continuous liner comprises one of silicon nitride, titanium nitride, titanium tungsten, tantalum nitride, nickel and copper.

17. The structure of claim 11, wherein the chip comprises at least one trench on the backside and which is lined with the continuous liner.

18. The structure of claim 17, wherein the at least one trench is filled with polymer material.

19. The structure of claim 11, further comprising a gap fill material on the substrate and adjacent to the chip, the gap fill material being planar with the continuous liner on the backside of the chip.

20. A method comprising:
partially dicing a device substrate from a first side of the device substrate;
lining the first side of the device substrate with a continuous liner material on all of the sidewalls which are formed at a region of the partially dicing;
completing the dicing of the device substrate from a second side of the device substrate to form a plurality of chips; and
mounting the second side of each of the plurality of chips to a substrate with the continuous liner now being on an upper surface and all of the sidewalls of the chip, the upper surface being opposite to a mounting surface of the chip to the substrate.
